(19) United States
(12) Patent Application Publication
(10) Pub. No.: US 2013/0295757 A1
(43) Pub. Date: Nov. 7, 2013

(54) SHORT GATE-LENGTH HIGH ELECTRON-MOBILITY TRANSISTORS WITH ASYMMETRIC RECESS AND SELF-ALIGNED OHMIC ELECTRODES

(71) Applicant: BAE Systems Information and Electronic Systems Integration Inc., (US)

(72) Inventors: Dong Xu, Nashua, NH (US); Kanin Chu, Nashua, NH (US); Pane-chane Chao, Nashua, NH (US)

(21) Appl. No.: 13/875,385

(22) Filed: May 2, 2013

Related U.S. Application Data
(60) Provisional application No. 61/642,510, filed on May 4, 2012.

(51) Int. Cl. H01L 21/28

(52) U.S. Cl. CPC H01L 21/28008
USPC 438/586

(57) ABSTRACT

A method for fabricating InP-based high electron-mobility transistors (HEMTs) and GaAs-based metamorphic electron-mobility transistors (MHEMTs) by utilizing asymmetrically recessed Γ-gates and self-aligned ohmic electrodes is disclosed. The fabrication starts with mesa isolation, followed by gate recess and gate metal deposition, in which the gate foot is placed asymmetrically in the recess groove, with the offset towards the source. It is important to use Γ-gates as the shadow mask for ohmic metal deposition, because it allows a source-gate spacing as small as 0.1 micron, greatly reducing the critical source resistance, and it retains a relatively large gate-drain spacing, enabling a decent breakdown voltage when coupled with the asymmetric gate recess. It is also critical to maintain a large stem height of the Γ-gates to assure a sufficient gap between the top of the gates and the ohmic metal after its deposition to reduce the parasitic capacitance. The uniqueness of this technology would best fit the applications that require low voltage and/or low DC power consumption.

### CROSS-REFERENCE TO RELATED APPLICATIONS

This Application claims rights under 35 USC §119(e) from U.S. Application Ser. No. 61/642,510 filed 4 May 2012 the contents of which are incorporated herein by reference.

### TECHNICAL FIELD

Embodiments are generally related to transistors. Embodiments also relate to high electron-mobility transistors. Embodiments additionally relate to a system and method for fabricating InP-based high electron-mobility transistors (HEMTs) and GaAs-based metamorphic electron-mobility transistors (MHEMTs) by utilizing asymmetrically recessed Γ-gates and self-aligned ohmic electrodes.

### BACKGROUND OF THE INVENTION

Indium phosphide (InP) based high electron-mobility transistor (HEMT) and gallium arsenide (GaAs)-based metamorphic electron-mobility transistor (MHEMT) with short gate lengths are well known for their outstanding performance for millimeter- and submillimeter-wave applications. While the gate length reduction has been the most important way of improving performance of III-V HEMTs over the past decades, limitation of this approach begins to emerge that is disclosed in a D. Xu, X. P. Yang, Wendell M. T. Kong, P. Seekell, K. Louie, L. Mt. Pleasant, L. Mohnkern, D. Dugas, K. Chu, H. Karimy, K. H. G. Duh, P. M. Smith. P. C. Chao, “Gate-length scaling of ultra-short metamorphic high electron-mobility transistors with asymmetrically recessed gate contacts for millimeter- and submillimeter-wave applications,” IEEE Trans. Electron Devices, vol. 58, pp. 1408-1417, 2011. One observation is that the devices showing the highest maximum extrinsic transconductance gₘ are actually those with gate lengths between 35-70 nm as disclosed in D. Xu, T. Suemitsu, J. Osaka, Y. Umeda, Y. Yamane, Y. Ishii, T. Ishii, and T. Tamamura, “InP-based depletion- and enhancement-mode modulation-doped field-effect transistors for ultrahigh-speed applications: An electrochemical fabrication technology,” IEEE Trans. Electron Devices, vol. 47, pp. 33-43, 2000 and M. Lange, X. B. Mei, T. P Chin, W. Yoshida, W. R. Deal, P. H. Liu, J. Lee, J. Uyeda, L. Deng, J. Wang, W. Liu, D. T. Li, M. E. Barsky, Y. M. Kim, V. Radisic, and R. Lai, “InAs/InGaAs composite channel HEMT on InP: Tailoring InGaAs thickness for performance,” Proc. Int. Conf. Indium Phosphide and Related Materials, pp. 1-4, May 25-29, 2008, the contents of which are incorporated herein by reference. Such devices outperform those with even gate lengths below 30 nm or shorter; in particular, the InP-based HEMT with record 3 S/mm gₘ reported in H. Matsuzaki, T. Maruyama, T. Enoki, and M. Tokumitsu, “3 S/mm extrinsic transconductance of InP-based high electron mobility transistor by vertical and lateral scale-down,” Electron. Lett., vol. 42, pp. 883-884, 2006, the contents of which are incorporated herein by reference has a gate length of 60 nm.

Similarly, the highest maximum stable gain (MSG) at 110 GHz attained thus far is from devices with not-so-short gate lengths ranging from 36 to 50 nm as disclosed in R. Lai, X. B. Mei, W. R. Deal, W. Yoshida, Y. M. Kim, P. H. Liu, J. Lee, J. Uyeda, V. Radisic, M. Lange, T. Gaier, L. Samoska and A. Fung, “Sub 50 nm InP HEMT device with fₘₐₓ greater than 1 THz,” Proc. International Electron Devices Meeting, pp. 609-611, Dec. 10-12, 2007; D. Xu, M. T. Kong, X. P. Yang, P. M. Smith, D. Dugas, P. C. Chao, G. Cueva, L. Mohnkern, P. Seekell, L. Mt. Pleasant, B. Schmanski, K. H. G. Duh, H. Karimy, A. Immorlica, and J. J. Komiak, “Asymmetrically recessed 50-nm gate-length metamorphic high electron-mobility transistor with enhanced gain performance,” IEEE Electron Device Lett., vol. 29, pp. 4-8, 2008; and D. Xu, W. M. T. Kong, X. P. Yang, L. Mohnkern, P. Seekell, L. Mt. Pleasant, K. H. G. Duh, P. M. Smith, and P. C. Chao, “50-nm metamorphic high-electron-mobility transistors with high gain and high breakdown voltages,” IEEE Electron Device Lett., vol. 30, pp. 793-795, 2009, the contents of which are incorporated herein by reference. Therefore, there is need for finding approaches beyond gate-length reduction to improve performance of HEMTs.

The source-drain spacing becomes an increasingly important limiting factor of the performance of HEMTs when the gate length is reduced in particular to sub-100 nm or even lower. A recent simulation of a 35-nm HEMT has suggested that a decrease in the source-drain spacing from 1.5 to 0.5 μm will result in an increase in the overall drive current to 1250 from approximately 725 mA/mm as disclosed in J. S. Ayubi-Moak, D. K. Ferry, S. M. Goodnick, R. Akis, and M. Saraniti, “Simulation of ultrasubmicrometer-gate In_{0.52}Al_{0.48}As/In_{0.75}Ga_{0.25}As/In_{0.52}Al_{0.48}As/InP pseudomorphic HEMTs using a full-band Monte Carlo simulator,” IEEE Trans. Electron Devices, vol. 54, pp. 2327-2338, 2007, the contents of which are incorporated herein by reference. Correspondingly, the gₘ would increase to over 2000 from about 970 mS/mm, indicating that a much faster overall device response can be expected with the reduction of the source-drain spacing to 0.5 μm or below. The aforementioned performance enhancement is attributed to the reduction in the effective internal source-drain series resistance.

Self-aligned (SAL) HEMT is the most straightforward approach to realizing greatly reduced source-drain spacing and source-drain resistance. This technology, however, is not a new device concept and it has been explored in both the fabrication feasibility and performance potential for many years. For example, there were reports on the employment of refractory gate as the implantation mask as disclosed in J. H. Huang, J. K. Abrokwah, and W. J. Ooms, “Nonalloyed InGaAs/GaAs ohmic contacts for self-aligned ion implanted GaAs heterostructure field effect transistors,” Appl. Phys. Lett., vol. 61, pp. 2455-2457, 1992, the contents of which are incorporated herein by reference. There were also reports of the adoption of a non-alloyed tungsten ohmic process as disclosed in N. Waldron, D.-H. Kim, and Jesus A. del Alamo, “90 nm Self-aligned enhancement-mode InGaAs HEMT for logic applications,” Proc. International Electron Devices Meeting, pp. 633-636, Dec. 10-12, 2007, the content of which are incorporated herein by reference Nguyen et al. demonstrated state-of-the-art current gain cut-off frequency of 340 GHz with a 50-nm SAL InP-based HEMT in 1992 as is disclosed in L. D. Nguyen, A. S. Brown, M. A. Thompson, and L. M. Jelloian, “50-nm self-aligned-gate pseudomorphic AlInAs/GaInAs high electron mobility transistors,” IEEE Trans. Electron Devices, vol. 39, pp. 2007-2014, 1992, the contents of which are incorporated herein by reference.

Despite the successful demonstration of some excellent results on current gain cut-off frequencies, it is also clear that the self-aligned device normally suffers from lower breakdown voltages and often exhibits excessively high output conductance, making it a poor candidate for various millimeter- and submillimeter-wave applications. Therefore, a need exists for a way to address the high parasitic and low breakdown issue of short gate HEMT's with a novel fabrication technology.

### BRIEF SUMMARY

The following summary is provided to facilitate an understanding of some of the innovative features unique to the disclosed embodiment and is not intended to be a full description. A full appreciation of the various aspects of the embodiments disclosed herein can be gained by taking the entire specification, claims, drawings, and abstract as a whole.

It is, therefore, one aspect of the disclosed embodiments to provide for transistors.

It is another aspect of the disclosed embodiments to provide for HEMTs.

It is a further aspect of the present invention to provide for a system and method for fabricating InP-based HEMTs and GaAs-based MHEMTs by utilizing asymmetrically recessed Γ-gates and self-aligned ohmic electrodes.

The aforementioned aspects and other objectives and advantages can now be achieved as described herein. The present invention makes use of asymmetrically recessed Γ-gates and self-aligned ohmic electrodes. The fabrication starts with mesa isolation, followed by gate recess and gate metal deposition, in which the gate foot is placed asymmetrically in the recess groove, with the offset towards the source. It is important to use Γ-gates as the shadow mask for ohmic metal deposition, because it allows a source-gate spacing as small as 0.1 micron, greatly reducing the critical source resistance, and it retains a relatively large gate-drain spacing, enabling a decent breakdown voltage when coupled with the asymmetric gate recess. It is also critical to maintain a large stem height of the Γ-gates to assure a sufficient gap between the top of the gates and the ohmic metal after its deposition to reduce the parasitic capacitance. The process described above leads to HEMT devices with record high transconductance of 3 S/mm, higher than 4V off-state breakdown voltage, and at least 1.5V on-state breakdown voltage.

It is to be understood that both the foregoing general description and the following detailed description are exemplary and explanatory only and are intended to provide further explanation of the invention as claimed. The accompanying drawings are included to provide a further understanding of the invention and are incorporated in and constitute part of this specification, illustrate several embodiments of the invention, and together with the description serve to explain the principles of the invention.

### BRIEF DESCRIPTION F THE DRAWINGS

The accompanying figures, in which like reference numerals refer to identical or functionally-similar elements throughout the separate views and which are incorporated in and form a part of the specification, further illustrate the disclosed embodiments and, together with the detailed description of the invention, serve to explain the principles of the disclosed embodiments.

FIG. 1A illustrates fabrication process of self-aligned MHEMTs, in accordance with the disclosed embodiments;

FIG. 1B illustrates a cross sectional view of 50-nm MHEMT with self-aligned ohmic metal defined by the Γ-gate as the shadow mask, in accordance with the disclosed embodiments;

FIG. 2 illustrates a graph showing source resistance and total source-drain resistance as a function of the gate recess width for 50-nm asymmetrically recessed MHEMTs with conventional and self-aligned ohmic metal, in accordance with the disclosed embodiments;

FIG. 3A illustrates a graph showing comparison of output IV characteristics of 50-nm conventional and self-aligned MHEMTs with a recess width of 150 nm, in accordance with the disclosed embodiments;

FIG. 3B illustrates a graph showing comparison of output IV characteristics of 50-nm conventional and self-aligned MHEMTs with a recess width of 275 nm, in accordance with the disclosed embodiments;

FIG. 4 illustrates a graph showing maximum drain current and maximum extrinsic transconductance as a function of the gate recess width for 50-nm asymmetrically recessed MHEMTs with conventional and self-aligned ohmic before passivation, in accordance with the disclosed embodiments;

FIG. 5 illustrates a graph showing two-terminal off-state breakdown voltage as a function of the gate recess width for 50-nm asymmetrically recessed MHEMTs with conventional and self-aligned ohmic metal, in accordance with the disclosed embodiments;

FIG. 6 illustrates a graph showing three-terminal on-state breakdown voltage as a function of gate recess width for 50-nm asymmetrically recessed MHEMTs with conventional and self-aligned ohmic metal, in accordance with the disclosed embodiments;

FIG. 7 illustrates a graph showing pinch-off voltage Vₚₒ and the drain-induced barrier lowering DIBL as a function of drain bias of a 50-nm self-aligned MHEMT with a recess width of 150 nm, in accordance with the disclosed embodiments;

FIG. 8A illustrates a graph showing transconductance as a function of gate bias for a 50-nm asymmetrically recessed self-aligned MHEMT with a recess width of 150 nm at different drain bias conditions, in accordance with the disclosed embodiments;

FIG. 8B illustrates a graph showing maximum extrinsic transconductance as a function of drain bias for asymmetrically recessed self-aligned 50-nm MHEMTs with a recess width of 150 nm, in accordance with the disclosed embodiments. The state-of-the-art transconductance results reported in relevant references have been included as open squares for comparison;

FIG. 9 illustrates a graph showing the voltage gain gₘ/gₒ as a function of drain bias for a 50-nm SAL MHEMT with 150-nm asymmetrical recess, in accordance with the disclosed embodiments;

FIG. 10A illustrates a graph showing current gain and maximum stable gain calculated from measured S-parameters from 0.5 to 110 GHz for a 50-nm self-aligned MHEMT with a 150-nm recess groove, which has a 2×10 μm gate periphery and is biased at a V_{ds} of 0.7 V and I_{ds} of 10 mA, in accordance with the disclosed embodiments; and

FIG. 10B illustrates a graph showing the maximum stable gain at 110 GHz as a function of the gate bias and drain bias for the same 50-nm self-aligned MHEMT in FIG. 10A, in accordance with the disclosed embodiments.

### DETAILED DESCRIPTION

The particular values and configurations discussed in these non-limiting examples can be varied and are cited merely to illustrate at least one embodiment and are not intended to limit the scope thereof.

### 1. Fabrication of Asymmetrically Recessed 50nm MHEMT with Greatly Reduced Source-Drain Spacing

Molecular beam epitaxy (MBE) was used to grow the MHEMT structures on semi-insulating GaAs substrates, The epitaxy began with the growth of a graded InGaAlAs metamorphic buffer layer, which was followed by active layers including a bottom i-InAlAs barrier, a bottom silicon spike doping of 1×10¹² cm⁻², a bottom i-InAlAs spacer, a high-indium channel consisting of InAs and InGaAs layers a top i-InAlAs spacer, a top silicon spike doping of 5×10¹² cm⁻², an i-InAlAs gate layer, and a highly-doped InGaAs cap layer. Besides, an extra silicon planar doping was introduced in the InAlAs gate layer slightly below its interface with the InGaAs cap layer to realize the non-alloyed ohmic contact. All the InGaAs and InAlAs layers above the metamorphic buffer are lattice-matched to indium phosphide. Meanwhile, the gate and channel layers have been thinned down to a total thickness of 22 nm to improve the aspect ratio. At room temperature, this epitaxial design typically shows a sheet carrier density of 4.6×10¹² cm⁻² and electron mobility of 11200 cm²/V-s,

The device fabrication began with mesa isolation through wet-chemical etching, followed by metal deposition to define alignment mark for electron-beam lithography, as well as the definition of the ohmic electrodes for a few devices to monitor the drain current at gate recess and serve as reference. The gate recess and gate metal deposition were then performed on the mesa strips both with ohmic metal, which serves as the source and drain electrodes, and without ohmic metal, where the SAL ohmic will be defined after the gate metal is deposited. Two separate electron lithography steps were taken for the gate recess and gate deposition so that the footprint of the 50-nm gate could be asymmetrically placed at typically 30 nm away from the source end of the recess groove to minimize the source resistance; meanwhile, the total recess width is from 150 to 350 nm. The gate-to-channel distance of the fabricated devices (both conventional and SAL) is approximately 8 nm.

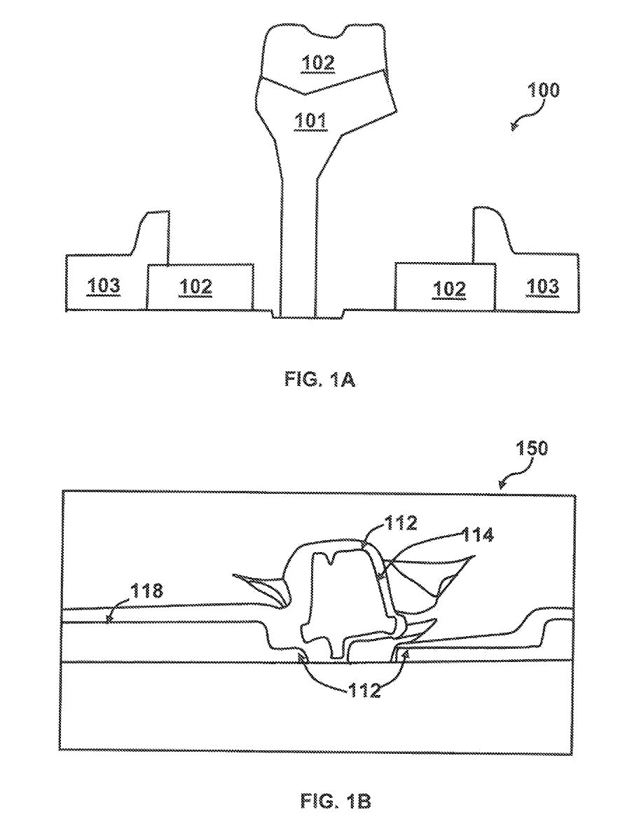

The key part of the whole process is the fabrication of the SAL ohmic electrodes to reduce the source and drain spacing by using the gates as the shadow mask for ohmic metal deposition; the fabrication sequence 100 is illustrated in FIG. 1A.

The fabrication sequence 100 includes the definition of the Γ-gate with electron-beam lithography, evaporation of ohmic metal with the Γ-gate as the shadow mask and the definition of the interconnect metal by optical lithography depicted by the reference numerals 101, 102 and 103 respectively.

Low ohmic contact resistance can be obtained without a conventional ohmic alloying process and it is essentially independent of the choice of the metal stack. The above feature comes as a result of the “built-in” tunneling between the cap and channel layers brought by the epitaxial layer design with a silicon spike slightly underneath the cap, which greatly lowers the conduction band of the InAlAs gate layer and therefore significantly reduces its effective potential barrier height to the InGaAs cap layer as disclosed in S. Kraus, H. Heiβ, D. Xu, M. Sexl, G. Böhm, G. Tränkle, and G. Weimann, “InGaAs/InAlAs HEMTs with extremely low source and drain resistance,” Electron. Lett., vol. 32, pp. 1619-1621, 1996, the contents of which are incorporated herein by reference. However, the thickness of the ohmic stack has to be appropriate for the stem height of the specific Γ-gate used as the evaporation mask to avoid incurring excessive parasitic capacitance between the gate wing and the source electrode. The Γ-gate chosen for this process allows the critical gate-source spacing to be reduced to as small as 0.1 μm, simultaneously reducing the source resistance down to at least 0.13Ω-mm.

The remaining processing steps consisted of device passivation, interconnect metal deposition, and backside process including thinning, via hole and back metal. FIG. 1B shows a transmission electron microscope photograph 150 of the cross section of a fabricated 50-nm SAL MHEMT with self-aligned ohmic metal 112 defined by the Γ-gate 114 as the shadow mask and ohmic metal interconnect 118;

The photograph 150 shows a 50-nm MHEMT with self-aligned ohmic metal defined by the Γ-gate as the shadow mask, fabricated on the epitaxial layers grown on GaAs substrate. The device has a gate-source spacing of approximately 0.1 μm and a total source-drain spacing of about 0.5 μm, which are significantly smaller than those of the conventional devices.

### 2. Impact of Reduced Source-Drain Spacing on Performance of 50-nm MHEMTs

A. Source Resistance and Total Source-Drain Resistance

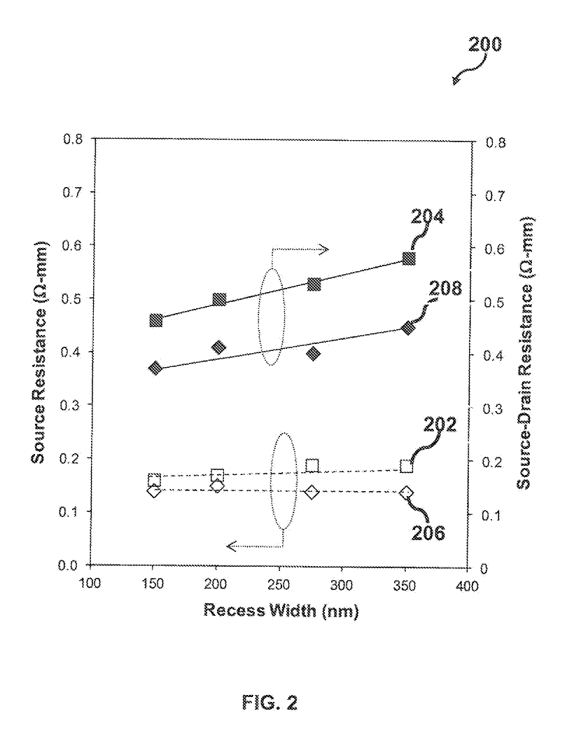

FIG. 2 illustrates a graph 200 showing source resistance (open symbols) and total source-drain resistance (solid symbols) as a function of the gate recess width for 50-nm asymmetrically recessed MHEMTs with conventional (squares) and self-aligned ohmic metal (diamonds). The source resistance was extracted by measuring the voltage drop between the source and drain when a small known current was injected between the gate and the source. The source-drain resistance was extracted by estimating the slope of the I-V curves at a gate bias of 0.6 V from the output characteristics of the device. As shown in graph 200, the conventional source resistance, conventional source-drain resistance, self-aligned source resistance, self-aligned source drain resistance is indicated by reference numerals 202, 204, 206 and 208 respectively.

FIG. 2 summarizes the dependence of parasitic resistances of MHEMTs on the recess width. One can notice that the source resistance is essentially independent of the recess width for both the conventional and the SAL devices. This is because both types of devices have a fixed gap between the gate and the source end of the recess groove and a fixed spacing between the gate and source electrodes when the recess groove extends towards the drain. However, the SAL devices still have a source resistance that is about 0.03Ω-mm lower as a result of their smaller gate-source spacing. On the other hand, the SAL devices show significantly lower total source-drain resistance than the conventional ones. For example, the SAL device with a 150-nm wide recess demonstrates a total source-drain resistance of 0.37Ω-mm, which is about 0.1Ω-mm lower than its conventional counterpart. This is because the total source-drain spacing of the SAL devices has been reduced to 0.5 μm from the 2 μm of conventional ones.

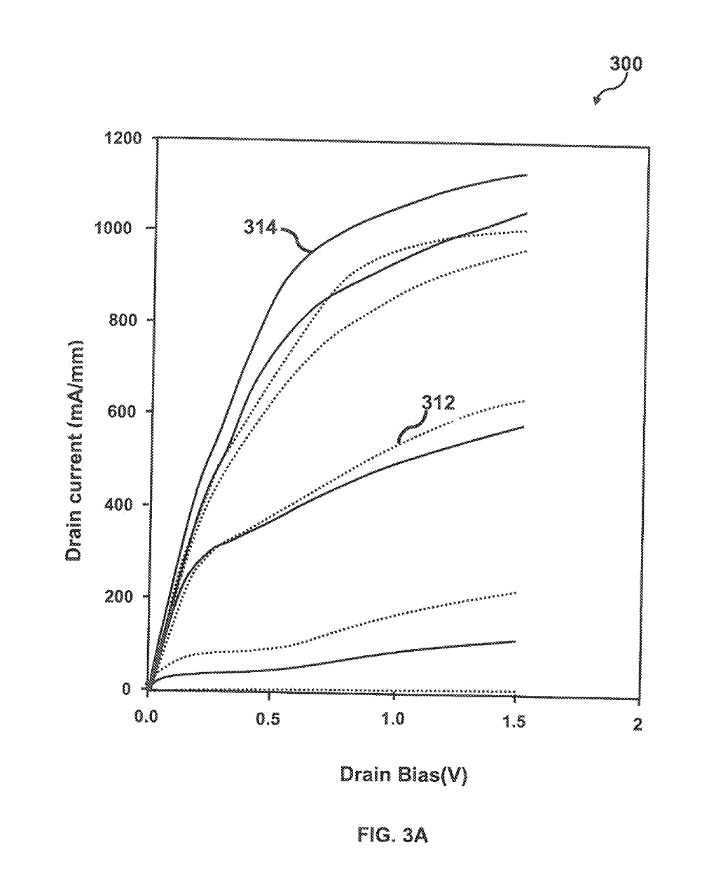

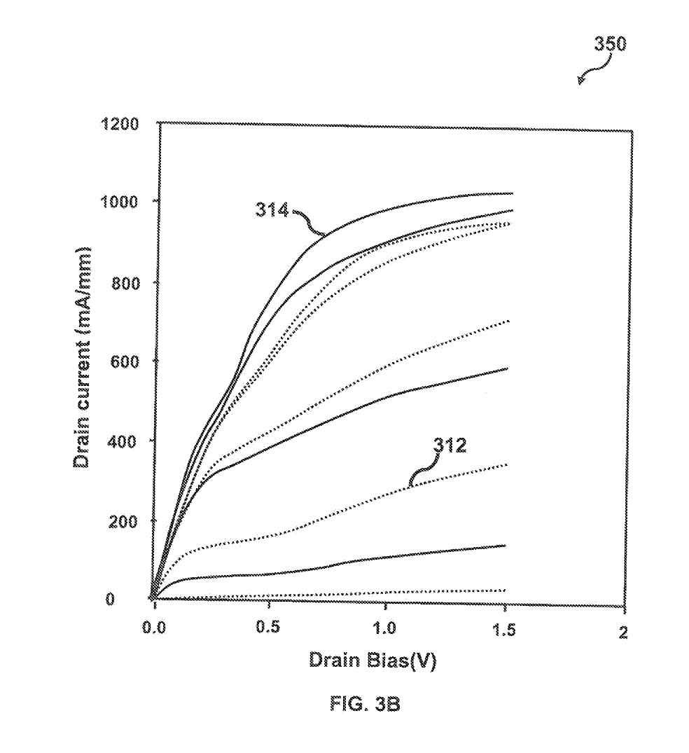

The benefits of reducing both the source and the total source-drain resistances show up in the improved IV characteristics of a 50-nm SAL device with a 150-nm recess width as graph 300 in FIG. 3A. The self-aligned IV characteristics are shown in solid lines 314 and the conventional IV characteristics are shown in dotted lines 312. While the SAL device retains the same sharp pinch-off characteristic as its conventional counterpart, it demonstrates a markedly enhanced drain current at low V_{ds} ranging from 0.2 to 0.5 V, an overall slightly lower output conductance, and significantly improved transconductance uniformity over a wide V_{ds} range. Similar improvement can also be readily found by comparing the IV characteristics of the 50-nm SAL and conventional devices with the same 275-nm gate recess grooves, as shown as graph 350 in FIG. 3B. In FIGS. 3A and 3B, the self-aligned and conventional IV characteristics are shown in solid and dotted lines, respectively, In both graph 300 and 350, the gate bias V_{g}, for the top curve is 0.6 V and V_{g}, step is −0.2 V.

B. Maximum Drain Current and Transconductance

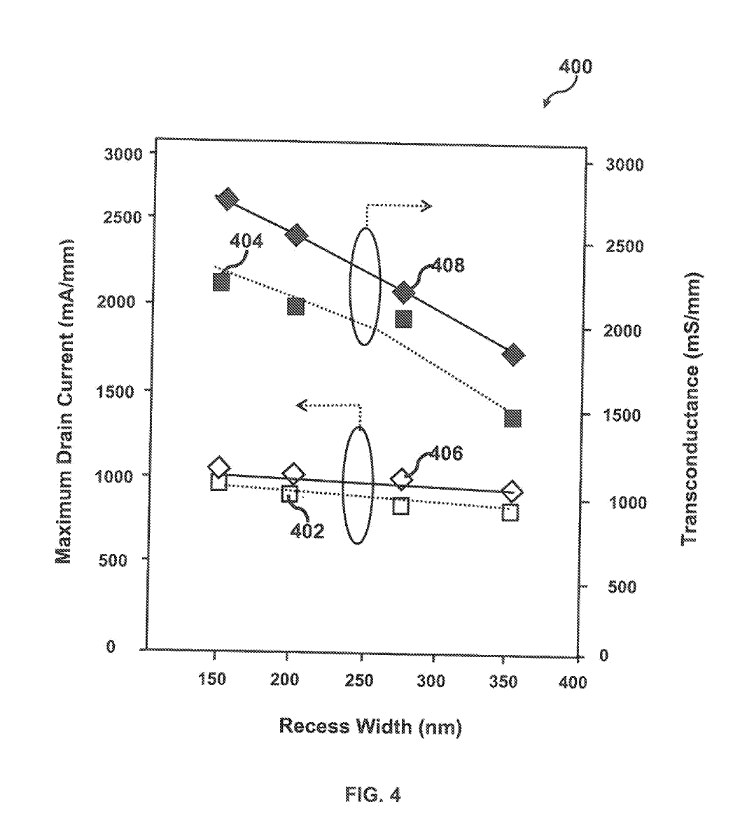

In FIG. 4 as shown in graph 400, SAL devices expectedly demonstrate both higher maximum drain current Iₘₐₓ and higher gₘ than the conventional with the same recess widths as a result of the reduction in gate-source spacing and source-drain spacing. The increase in Iₘₐₓ is around 10%, while the enhancement of gₘ is more than 20% when the self-aligned process is implemented. The conventional Iₘₐₓ, conventional gₘ, self-aligned Iₘₐₓ and self-aligned gₘ are indicated by reference numerals 402, 404, 406 and 408 respectively. The maximum drain current and maximum extrinsic transconductance were measured at a drain bias of 1 V, and the gate bias for maximum drain current was 0 6 V.

The greatly boosted gₘ observed in the SAL devices cannot be attributed only to the reduction in the source resistance. For example, if the source resistance of 0.13 and 0.16Ωmm is taken for the SAL and the conventional devices with the same 150-nm recess groove, their corresponding intrinsic transconductance would be estimated as 3.92 and 3.27 S/mm, respectively. Since the two aforementioned devices have essentially the same gate-to-channel distance, which is indicated by their similar pinch-off voltage, the higher intrinsic transconductance of the SAL device can be explained only by the higher effective electron velocity in its channel. This enhanced effective electron velocity could be largely due to the drastically reduced gate-source spacing of 0.1 μm in the SAL device, which leads to an earlier acceleration of electrons that are injected from the source as disclosed in R. Akis, N. Faralli, D. K. Ferry, S. M. Goodnick, K. A. Phatak, and M. Saraniti, “Ballistic transport in InP-based HEMTs,” IEEE Trans. Electron Devices, vol. 56, pp. 2935-2944, 2009 the contents of which are incorporated herein by reference.

C. Off-State Breakdown Voltage

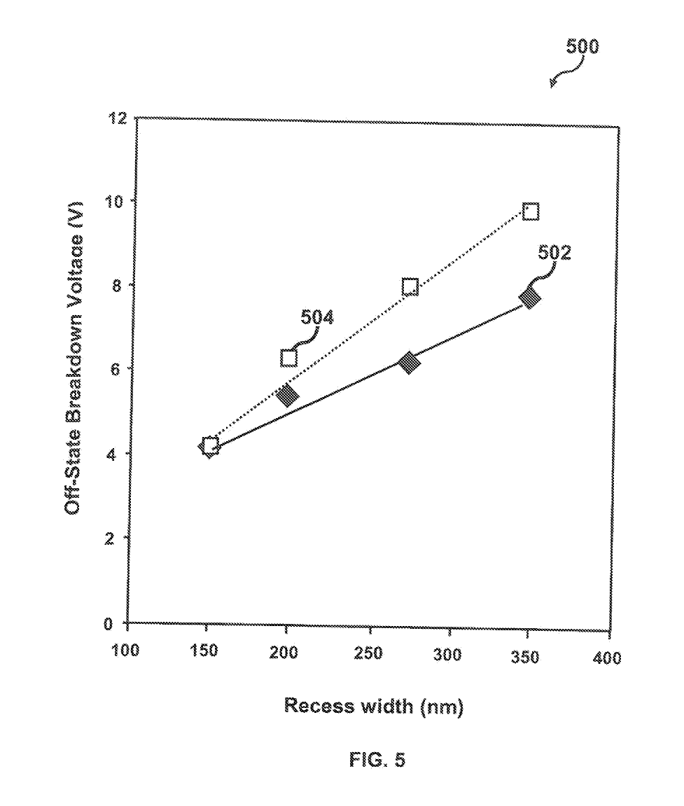

Because of the greatly reduced source-drain spacing, the self-aligned HEMTs used in prior arts typically suffer from low off-state breakdown voltage BV_{off}, defined as the gate-drain voltage at which a gate current I_{g} of 1 mA/mm is reached with the source electrode floating. The incorporation of asymmetric recess groove into the self-aligned device clearly leads to BV_{off} improvement. FIG. 5 summarizes a graph 500 showing BV_{off} dependence of SAL and conventional devices on the recess width. BV_{off} as high as 8 V has been achieved for the SAL device with 350-nm wide recess; even for the SAL device with a small recess width of 150 nm, BV_{off} higher than 4 V has also been demonstrated. In graph 500, the reference numerals 502 and 504 represents plots of self-aligned and convention devices, respectively.

D. On-State Breakdown Voltage

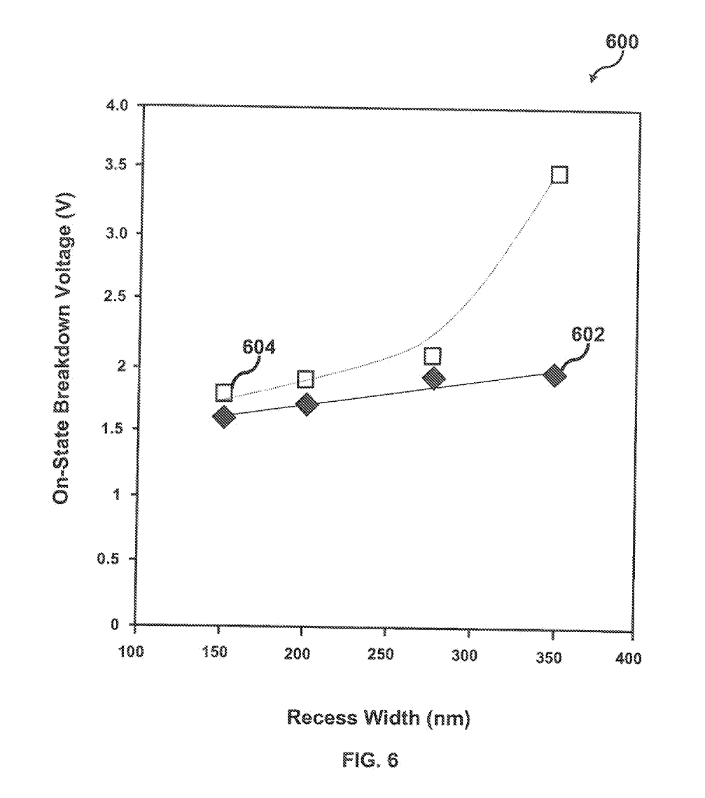

The three-terminal on-state breakdown voltage BVₒₙ, determines the drain bias that can be applied to the device without drawing excessive gate current I_{g}. BVₒₙ is defined as the drain-source voltage V_{ds} at which the gate current I_{g} reaches 1 mA/mm at the gate-source voltage V_{gs} corresponding to peak gₘ. In FIG. 6 as shown in graph 600, BVₒₙ of the SAL devices is dependent on the recess width. Despite the overall lower BVₒₙ of the SAL devices than that of the conventional ones, the SAL devices still demonstrate BVₒₙ as high as 2V, which is 2 times as high as those of the prior arts. In graph 600, the reference numerals 602 and 604 represents plots of self-aligned and convention devices, respectively.

### 3. Performance Enhancement of Self-Aligned MHEMTs

The major benefits of greatly reduced source-drain spacing in 50-nm SAL MHEMTs have been highlighted by the excellent IV characteristics in FIG. 3A and FIG. 3B: the reduced parasitic resistances, and the improved knee behaviors by eliminating most of the current collapse at low V_{ds}; both become even more apparent after the SiN passivation as a result of the alleviation of the surface depletion in the recess area. Meanwhile, it is also worthwhile to notice the sharp pinch-off characteristic of the SAL devices since it clearly indicates the minimum short channel effect, which is further confirmed by the small shift of pinch-off voltage Vₚₒ, and the low drain-induced barrier lowering (DIBL), which is defined by Equation (1) as follows:

DIBL@V_{ds}=(Vₚₒ@V_{ds}−Vₚₒ@0.1V)/(0.1V−V_{ds}), (Equation (1)

where the Vₚₒ is defined as the gate-source voltage V_{gs} at which the drain current reaches 1 mA/mm at a given drain source V_{ds}.

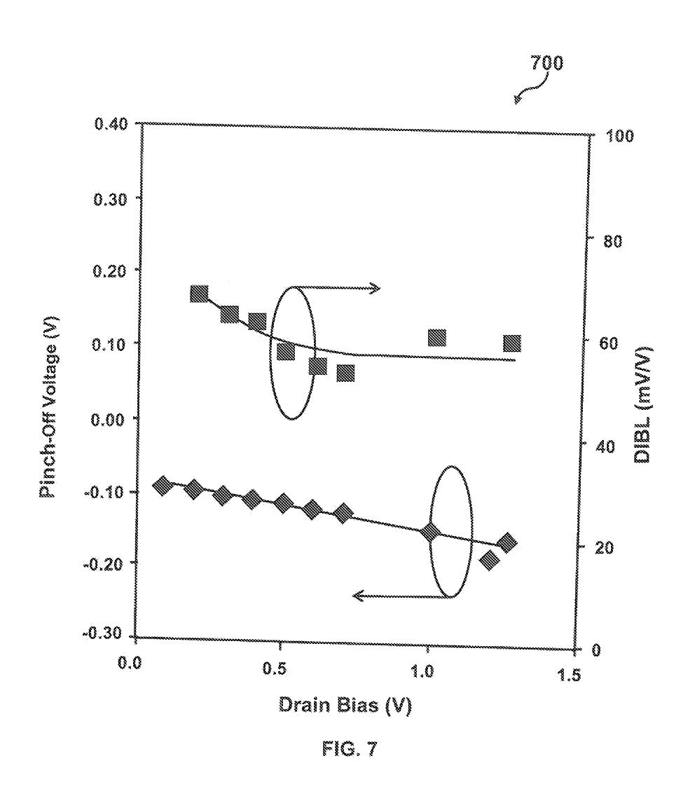

In FIG. 7 as shown in graph 700, the SAL MHEMT with a 150-nm recess groove displays a Vₚₒ shift of mere 68 mV when V_{ds} is increased from 0.1 to 1.25 V. DIBL has been estimated to be 60 mV/V within this V_{ds} range, comparable to that of the state-of-the-art devices reported thus far (for example, the non-self-aligned 40-nm InP HEMTs for logic applications as disclosed by D. H. Kim, and J. A. del Alamo, “Scalability of sub-100 nm InAs HEMTs on InP substrate for future logic applications,” IEEE Trans. Electron Devices, vol. 57, pp. 1504-1511, 2010, the contents of which are incorporated herein by reference).

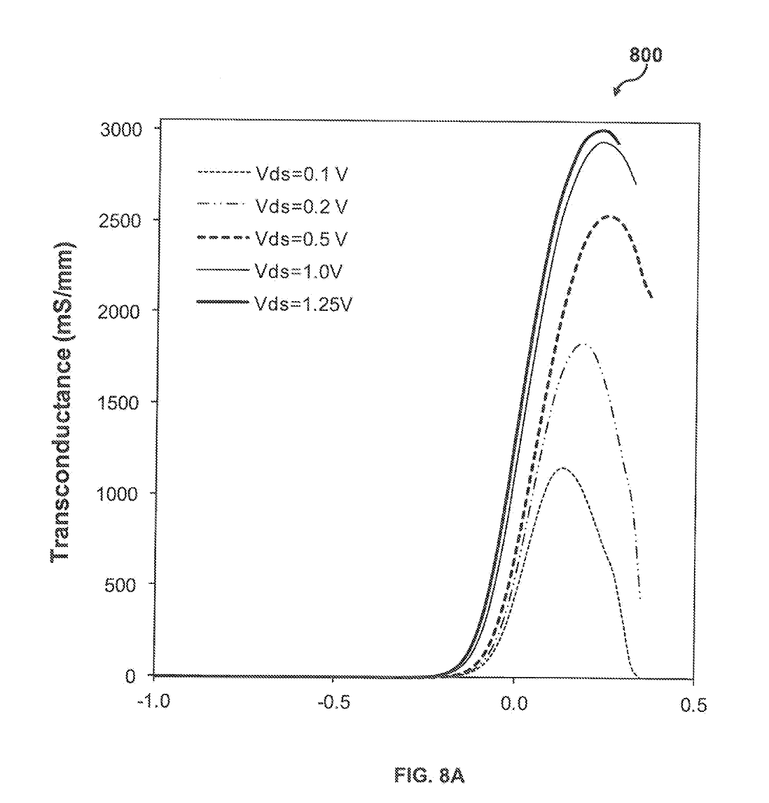

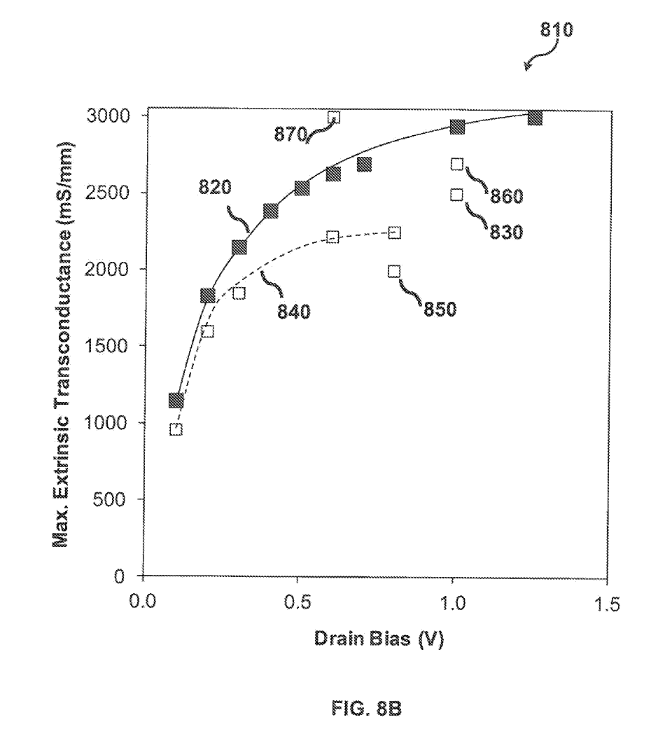

The excellent IV characteristics and the well contained short channel effects of the SAL devices are echoed by their superior gₘ performance, especially under the low V_{ds} conditions. The graph 800 in FIG. 8A shows the gₘ of the 50-nm SAL device with a 150-nm recess width reaches 2.94 and 3.05 S/mm at V_{ds} of 1 and 1.25 V, respectively; this represents about 20% improvement over the gₘ of 2.5 S/mm of this device before passivation as shown in FIG. 4. Furthermore, high gₘ of 1.1, 1.8 and 2.5 S/mm can be reached even at low V_{ds} of 0.1, 0.2 and 0.5 V, respectively, making this type of device a very attractive candidate for applications requiring low voltage operation and/or low DC power consumption.

The graph 810 in FIG. 8B summarizes the V_{ds} dependence of gₘ for the 50-nm SAL MHEMT referred by numeral 820 with a 150-nm asymmetrical recess groove, as well as the gₘ values of state-of-the-art HEMTs and MHEMTs over a wide V_{ds} range that were reported over the past decade as is disclosed by A. Leuther, A. Tessmann, M. Dammann, C. Schwoerer, M. Schlechtweg, M. Mikulla, R. Loesch, and G. Weimann, “50 nm MHEMT technology for G- and H-band MMICs,” in Proc. Int. Conf. Indium Phosphide and Related Materials, pp. 24-27 May 14-18, 2007 (referred by numeral 830); K. Shinohara, W. Ha, and B. Brar, “Extremely high gₘ>2.2 S/mm and f_{T}>550 GHz in 30-nm enhancement InP-HEMTs with Pt/Mo/Ti/Pt/Au buried gate,” in Proc. Int. Conf. Indium Phosphide and Related Materials, pp. 18-21, May 14-18, 2007 (referred by numeral 840); W. Ha, K. Shinohara, and B. Brar, “Enhancement mode metamorphic HEMT on GaAs substrate With 2 S/mm gₘ and 490 GHz f_{T},” IEEE Electron Device Lett., Vol. 29, pp. 419-421, 2008 (referred by numeral 850); M. Lange, X. B. Mei, T. P Chin, W. Yoshida, W. R. Deal, P. H. Liu, J. Lee, J. Uyeda, L. Deng, J. Wang, W. Liu, D. T. Li, M. E. Barsky, Y. M. Kim, V. Radisic, and R. Lai, “InAs/InGaAs composite channel HEMT on InP: Tailoring InGaAs thickness for performance,” Proc. Int. Conf. Indium Phosphide and Related Materials, pp. 1-4, May 25-29, 2008 (referred by numeral 860), and H. Matsuzaki, T. Maruyama, T. Enoki, and M. Tokumitsu, “3 S/mm extrinsic transconductance of InP-based high electron mobility transistor by vertical and lateral scale-down,” Electron. Lett., vol. 42, pp. 883-884, 2006 (referred by numeral 870), the contents of which are incorporated herein by reference.

The 50-nm SAL MHEMT outperforms most of the other devices and matches the 3 S/mm of the best InP-based device, setting a new gₘ record for the GaAs-based field-effect transistor. Also noticed that the gₘ achieved is much higher than the 2 S/mm predicted by the simulation results on a similar device with a 35-nm gate length and a 0.55-μm source-drain spacing, although the predicted maximum current matches the actual device very well. One possible reason for this discrepancy is that the assumed gate-to-channel distance in the simulation work is somewhat larger than that of actual device used, as the simulation device displays a more negative Vₚₒ. It is also possible that the simulation should take into account the effects of reduced gate-source spacing in addition to the reduced parasitic resistance; the reduced gate-source spacing in SAL devices appears to play a role that cannot be ignored. The SAL devices with larger recess widths of 200, 275 and 350 nm also demonstrate high gₘ values of 2.6, 2.1 and 2.0 S/mm at V_{ds} of 1 V, respectively. All these record performance levels highlight the most important advantage of implementing the SAL technology.

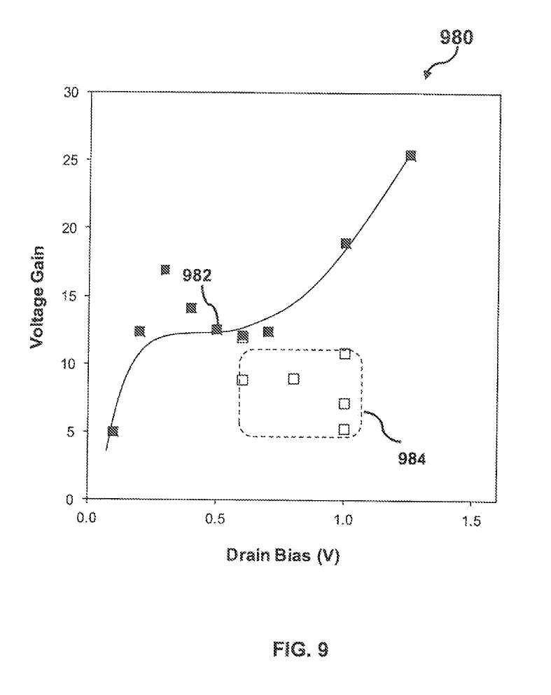

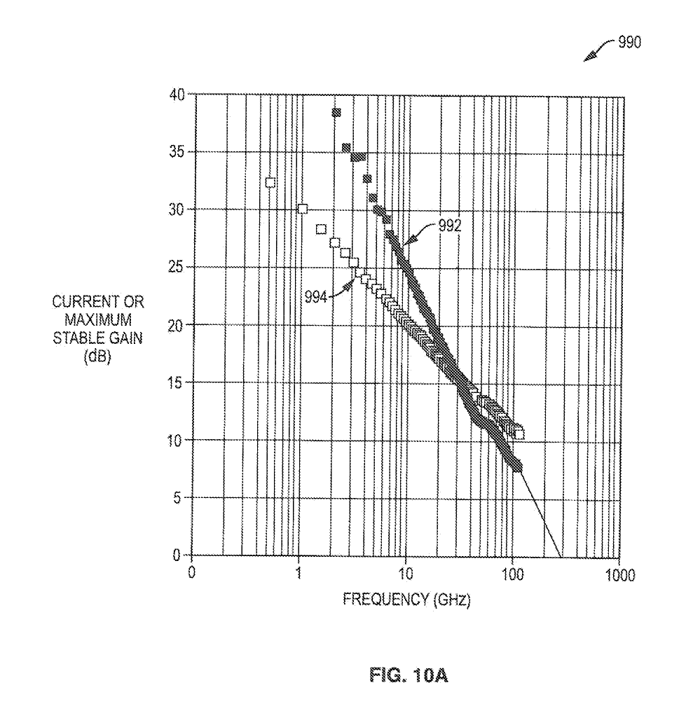

FIG. 9 illustrates a graph 980 showing the voltage gain gₘ/gₒ as a function of drain bias referred by numeral 982 for a 50-nm SAL MHEMT with 150-nm asymmetrical recess, using the gₘ reported in FIG. 8B and the output conductance gₒ values extracted from the IV characteristics of the same device. The reduction of the source-drain spacing does not result in an enhanced gₒ; on the contrary, FIG. 3 indicates that the gₒ of the SAL MHEMTs is actually somewhat lower than that of conventional ones with the same recess widths, which can be attributed to the improved kink effects and better knee characteristics. The improvement in the knee behavior can also be partially related to the faster drain current saturation due to a sharper channel pinch-off on the drain side of the gate, resulting from a smaller gate-drain spacing in the SAL device. The gₒ of the SAL device with 150-nm recess in this invention is estimated at approximately 155 mS/mm at a Vds of 1 V. The state-of-the-art voltage gain results reported in relevant references under various V_{ds} conditions is also referred in the FIG. 9 with numeral 984.

It is easy to note the trend in the plot that the voltage gain generally increases with the V_{ds}. This is because the gₘ typically increases with V_{ds} while gₒ essentially decreases with it. The plateau of the voltage gain around a V_{ds} of 0.5 V is due to the rapid increase in gₒ as a result of kink, typical in this materials system. The adoption of the asymmetric gate recess allows the device to be operated at a V_{ds} higher than other previously reported SAL devices in pursuit of a higher voltage gain. For the 50-nm asymmetrically recessed SAL device with a 150-nm recess width, a high voltage gain of 19 and 25 has been attained at V_{ds} of 1 and 1.25 V, respectively, comparing favorably with other conventional or SAL HEMTs under comparable V_{ds} conditions. The SAL device with a relatively small recess width like 150 nm that would offer the highest voltage gain and significance for applications requiring low voltage operation and/or low DC power consumption.

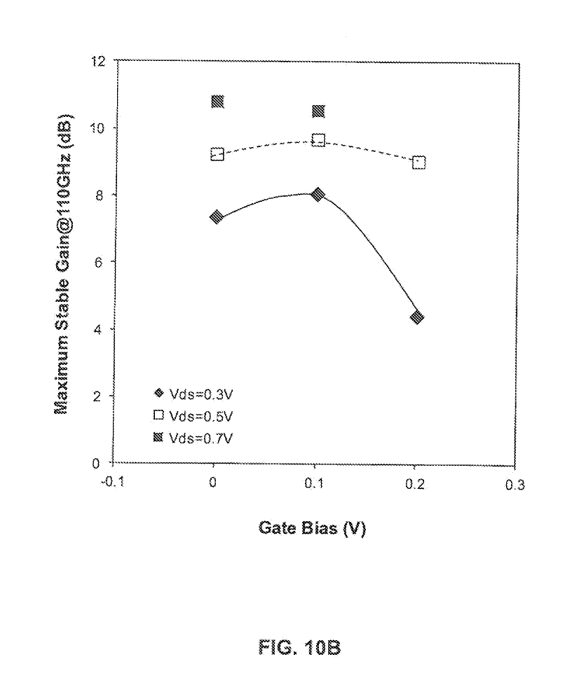

FIG. 10A illustrates a graph 990 showing current gain referred by numeral 992 and maximum stable gain (MSG) referred by numeral 994 obtained from on-wafer S-parameter measurement on a 2×10 μm for a 50-nm self-aligned MHEMT device with a 150-nm recess width over the frequency of 0.5-110 GHz. When biased at V_{ds} of 0.7 V and I_{ds} of 10 mA, the self-aligned device shows a MSG of 10.8 dB at 110 GHz, which is about 2-4 dB higher than the gain of the two reported state-of-the-art self-aligned InP HEMTs estimated at the same frequency. FIG. 10B illustrates a graph 996 showing the maximum stable gain at 110 GHz as a function of the gate bias and drain bias for the same 50-nm self-aligned MHEMT in FIG. 10A. FIG. 10B gives further details on the MSG dependence on the bias conditions, showing a higher gain at a higher V_{ds}.

### 4. Conclusion

A high-performance 50-nm MHEMT technology is realized by integration of asymmetrical recess and greatly reduced source-drain spacing via a self-aligned ohmic electrode process. The reduction of the source-drain spacing to 0.5 μm results in an extremely high extrinsic transconductance over a wide range of drain bias from 0.1 to 1.25 V. The achieved extrinsic transconductance of 3 S/mm is a new record for all HEMTs on GaAs and equals the best results with InP-based HEMTs. With the use of asymmetric recess, self-aligned MHEMTs also demonstrate remarkable improvement in other major figures of merit including BV_{off}, BVₒₙ, sub-threshold characteristics, I_{ON}/I_{OFF} ratio, and the voltage gain over the other self-aligned HEMTs reported so far. The uniqueness of this technology would best fit the applications that require low voltage and/or low DC power consumption.

While the present invention has been described in connection with the preferred embodiments of the various figures, it is to be understood that other similar embodiments may be used or modifications and additions may be made to the described embodiment for performing the same function of the present invention without deviating there from. Therefore, the present invention should not be limited to any single embodiment, but rather construed in breadth and scope in accordance with the recitation of the appended claims.

It will be appreciated that variations of the above disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. In the method for fabricating InP-based High Electron-Mobility Transistors (HEMTs) and GaAs-based metamorphic HEMTs comprising the steps of performing mesa isolation and performing gate recess and gate metal deposition, wherein the improvement comprises the step of:
integrating asymmetrically recessed Γ-gates and reducing source-drain spacing by a self-aligned ohmic electrode process.

2. The method of claim 1 wherein a footprint of about a 50-nm gate is asymmetrically placed at about 30 nm away from a source end of a recess groove to minimize the source resistance.

3. The method of claim 1 wherein total recess width is from about 150 to 850 nm.

4. The method of claim 1 wherein a gate-to-channel distance of the fabricated HEMT is approximately 8 nm.

5. In the method for fabricating InP-based High Electron-Mobility Transistors (HEMTs) and GaAs-based metamorphic HEMTs comprising the steps of performing mesa isolation and performing gate recess and gate metal deposition, wherein the improvement comprises the step of:
integrating asymmetrically recessed Γ-gates and reducing source-drain spacing by a self-aligned ohmic electrode process, wherein a footprint of about a 50-nm gate is asymmetrically placed at about 30 nm away from a source end of a recess groove to minimize the source resistance, and a total recess width is from about 150 to 350 nm.

6. The method of claim 5 wherein a gate-to-channel distance of the fabricated HEMT is approximately 8 nm.

7. In the method for fabricating InP-based High Electron-Mobility Transistors (HEMTs) and GaAs-based metamorphic HEMTs comprising the steps of performing mesa isolation and performing gate recess and gate metal deposition, wherein the improvement comprises the step of:
integrating asymmetrically recessed Γ-gates and reducing source-drain spacing by a self-aligned ohmic electrode process, wherein a footprint of about a 50-nm gate is asymmetrically placed at about 30 nm away from a source end of a recess groove to minimize the source resistance, and a gate-to-channel distance of the fabricated HEMT is approximately 8 nm.
